(19) United States
(12) Patent Application Publication
(10) Pub. No.: US 2025/0132134 A1
(43) Pub. Date: Apr. 24, 2025

(54) GAS SUPPLY ASSEMBLY AND SEMICONDUCTOR WAFER PROCESSING APPARATUS USING THE SAME

(71) Applicant: SAMSUNG ELECTRONICS CO., LTD., Suwon-si (KR)

(72) Inventors: Taeil Cho, Suwon-si (KR); Kyungsun Kim, Suwon-si (KR); Juho Kim, Suwon-si (KR); Changgil Son, Suwon-si (KR)

(73) Assignee: SAMSUNG ELECTRONICS CO., LTD., Suwon-si (KR)

(21) Appl. No.: 18/781,389

(22) Filed: Jul. 23, 2024

(30) Foreign Application Priority Data
Oct. 24, 2023 (KR) 10-2023-0143147

(51) Int. Cl. H01J 37/32; H01L 21/67; H01L 21/683

(52) U.S. Cl. CPC H01J 37/3244; H01J 37/32522; H01J 37/32715; H01J 2237/2001; H01J 2237/2007; H01J 2237/334; H01L 21/67017; H01L 21/6831

(57) ABSTRACT

A gas supply assembly includes: a heat control plate including a heater and a cooler; a gas distribution plate below the heat control plate and including a process gas distribution passage with process gas delivered therethrough and a heat regulating gas distribution passage with heat regulating gas delivered therethrough; a heat transfer pad below the gas distribution plate and including a dielectric material pad including an electrode therein; and a showerhead including a spraying nozzle in communication with the process gas distribution passage and discharging the process gas. The heat transfer pad further includes a process gas movement channel in communication with the process gas distribution passage of the gas distribution plate and a heat regulating gas movement channel in communication with the heat regulating gas distribution passage of the gas distribution plate.

### CROSS-REFERENCE TO RELATED APPLICATION(S)

This application claims priority under 35 U.S.C. 119(a) to Korean Patent Application No. 10-2023-0143147, filed on Oct. 24, 2023, in the Korean Intellectual Property Office, the entire disclosure of which is incorporated by reference herein for all purposes.

### BACKGROUND

The present disclosure relates to a gas supply assembly and a semiconductor substrate processing apparatus including the same.

Among semiconductor processes for manufacturing semiconductor devices, a deposition process or an etching process may be performed using a semiconductor wafer processing apparatus using plasma.

A surface temperature of a showerhead of a gas supply assembly may have a significant impact on wafer processing. If the surface temperature of the showerhead is relatively high, clogging (Not Open, NOP) may occur when etching a substrate wafer, and when the temperature of a showerhead is low, the mask becomes wider, causing a problem of the bowing critical dimension (CD) being larger.

Recently, in an etching process of high aspect ratio contacts (HARCs), which has been progressing due to demand for high integration of semiconductor substrates, there has been a need to improve a temperature control speed of a showerhead, which has a significant impact on the process.

An upper module of a semiconductor wafer processing apparatus of the related art may have a showerhead, a gas distribution plate, a temperature control plate, and the like stacked with each other. In general, a heater and a cooler may be built into a temperature control plate to control the temperature of the showerhead. In controlling the temperature of the showerhead, the upper module may have a large overall mass and may have a problem in which the speed of controlling the temperature of the showerhead is slow and limited due to a specific heat and thermal resistance of each plate.

If the temperature control of a showerhead is limited, it has a significant impact on the high aspect ratio contact etching process, causing problems such as clogging in certain wafer areas or the bowing critical dimension increasing due to excessive etching of the mask.

### SUMMARY

One or more example embodiments of the present disclosure provide a gas supply assembly that may quickly adjust a surface temperature of a showerhead.

Further, one or more example embodiments of the present disclosure provide a semiconductor wafer processing apparatus in which process efficiency and quality of semiconductor wafers may be improved by controlling temperature of a showerhead by dividing a wafer.

According to an aspect of an example embodiment, a gas supply assembly includes: a heat control plate including a heater and a cooler; a gas distribution plate below the heat control plate and including at least one process gas distribution passage a process gas, and at least one heat regulating gas distribution passage configured to deliver a heat regulating gas; a showerhead a spraying nozzle in communication with the at least one process gas distribution passage of the gas distribution plate, the spraying nozzle being configured to discharge the process gas; a heat transfer pad below the gas distribution plate and contacting the showerhead, the heat transfer pad including: a dielectric material pad, an electrode in the dielectric material pad, at least one process gas movement channel in communication with the at least one process gas distribution passage of the gas distribution plate, and at least one heat regulating gas movement channel in communication with the at least one heat regulating gas distribution passage of the gas distribution plate; and at least one gas collecting portion between the showerhead and the heat transfer pad and communicating with the at least one heat regulating gas movement channel of the heat transfer pad, each of the at least one gas collecting portion being a space configured to collect the heat regulating gas therein.

According to an aspect of an example embodiment, a semiconductor wafer processing apparatus including: a process chamber configured to accommodate a semiconductor wafer; a gas supply assembly in an upper portion of the process chamber and configured to discharge a process gas to the semiconductor wafer; and an electrostatic chuck configured to support the semiconductor wafer within the process chamber and generate plasma by opposing the gas supply assembly. The gas supply assembly includes: a heat control plate including a heater and a cooler; a gas distribution plate below the heat control plate and including at least one process gas distribution passage a process gas, and at least one heat regulating gas distribution passage configured to deliver a heat regulating gas; a showerhead a spraying nozzle in communication with the at least one process gas distribution passage of the gas distribution plate, the spraying nozzle being configured to discharge the process gas; a heat transfer pad below the gas distribution plate and contacting the showerhead, the heat transfer pad including: a dielectric material pad, an electrode in the dielectric material pad, at least one process gas movement channel in communication with the at least one process gas distribution passage of the gas distribution plate, and at least one heat regulating gas movement channel in communication with the at least one heat regulating gas distribution passage of the gas distribution plate; and at least one gas collecting portion between the showerhead and the heat transfer pad and communicating with the at least one heat regulating gas movement channel of the heat transfer pad, each of the at least one gas collecting portion being a space configured to collect the heat regulating gas therein.

### BRIEF DESCRIPTION OF THE DRAWINGS

The above and other aspects, features, and advantages of the present disclosure will be more clearly understood from the following detailed description, taken in conjunction with the accompanying drawings, in which:

FIG. 1 is a schematic cross-sectional view of a semiconductor wafer processing apparatus according to an example embodiment;

FIG. 2 is a schematic cross-sectional view of a gas supply assembly of the semiconductor wafer processing apparatus of FIG. 1;

FIG. 3 is a bottom view of a showerhead, viewed from a direction A of FIG. 2;

FIG. 4 is a schematic perspective view of a showerhead, viewed from the direction A of FIG. 2;

FIG. 5 is a schematic bottom view of a heat transfer pad according to an example embodiment;

FIG. 6 is a schematic bottom view of a heat transfer pad according to another embodiment;

FIG. 7 is a schematic bottom view of a heat transfer pad according to another embodiment;

FIG. 8 is a schematic diagram illustrating an electrical connection between an electrode embedded in a heat transfer pad and a showerhead according to an example embodiment;

FIG. 9 is a schematic diagram illustrating an electrical connection between an electrode embedded in a heat transfer pad and a showerhead according to another embodiment; and

FIG. 10 is a schematic diagram illustrating operation of plasma polymer according to showerhead temperature control in a semiconductor wafer processing apparatus of an example embodiment.

### DETAILED DESCRIPTION

Hereinafter, non-limiting example embodiments of the present disclosure will be described with reference to the accompanying drawings.

Example embodiments of the present disclosure may be modified to have various other forms, and are described to provide a more complete explanation of the present disclosure to those skilled in the art. Accordingly, the shapes and sizes of elements in the drawings may be exaggerated for clear description, and elements indicated by the same symbol in the drawings refer to the same element.

In the present disclosure, the meaning of “connection” is a concept including not only “directly connected” but also “indirectly connected” through other configurations. Additionally, in some cases, it is a concept including all “electrically connected things.”

In the present disclosure, expressions such as “first”, “second” and the like are used to distinguish one component from another component and do not limit the order and/or importance of the components. In some cases, the first component may be named the second component, and similarly, the second component may be named the first component without departing from the scope of the present disclosure.

The terminology used in the present disclosure is used to describe examples only and is not intended to limit the present disclosure. In the present disclosure, singular expressions include plural expressions, unless the context clearly indicates otherwise.

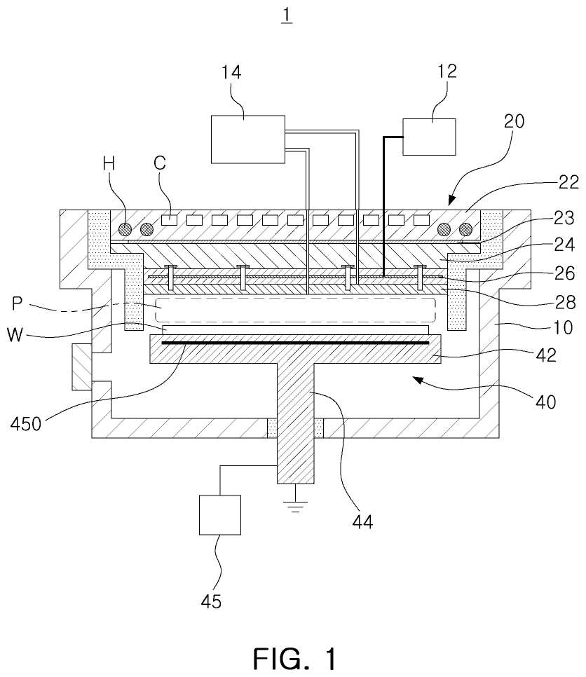

FIG. 1 is a schematic cross-sectional view of a semiconductor wafer processing apparatus according to an example embodiment.

A semiconductor wafer processing apparatus 1 according to an example embodiment of the present disclosure includes a process chamber 10, a gas supply assembly 20, and an electrostatic chuck 42.

The process chamber 10 may provide a space sealed from the outside, for a wafer W, and the sealed space may provide a space in which a process for the wafer W is performed. The semiconductor process may include at least one from among, for example, a deposition process, an etching process, and a cleaning process. The etching process may include an etching process of high aspect ratio contacts (HARCs) that is carried out in response to the demand for high integration of semiconductor substrates.

The process chamber 10 is formed of a metal material such as aluminum (Al) or the like. In an example embodiment, the process chamber 10 may include a substrate passage through which the wafer W is loaded or unloaded.

The gas supply assembly 20 may control a thickness distribution and film quality characteristics of a deposition material by adjusting a uniformity and distribution of the process gas sprayed on the wafer W within the process chamber 10. The gas supply assembly 20 receives process gas from a gas supply unit 14 and sprays the gas. The gas supply assembly 20 is connected to a power supply device 12, and generates plasma P between the electrostatic chuck 42 and the gas supply assembly 20 in the process chamber 10 by interacting with the electrostatic chuck 42 supporting the wafer W.

The electrostatic chuck 42 is an upper member of a wafer support 40 that supports the wafer W, and is vertically raised or lowered by power supply from a power supply unit 45 to adjust the distance thereof to the gas supply assembly 20.

The electrostatic chuck 42 may be a susceptor including a heating pattern 450, and the heating pattern 450 may heat the susceptor using power supplied from the outside. For example, the susceptor may be formed of a ceramic material such as aluminum nitride (AlN), aluminum oxide (Al₂O₃) or the like.

As an example, when a high aspect ratio contact etching process is performed on the wafer W on the electrostatic chuck 42 in the process chamber 10 in which the plasma P has been generated, the surface temperature of a showerhead 28 of the gas supply assembly 20 is a factor significantly affecting the reliability of the etching process.

If the surface temperature of the showerhead 28 is relatively high, clogging (Not Open, NOP) occurs when etching the wafer W, and if the surface temperature of the showerhead 28 is low, the mask becomes wider, which causes the problem of the bowing critical dimension (CD) becoming larger.

Therefore, controlling the temperature of the showerhead 28 may be implemented, which will be described in detail with respect to the gas supply assembly 20 described below.

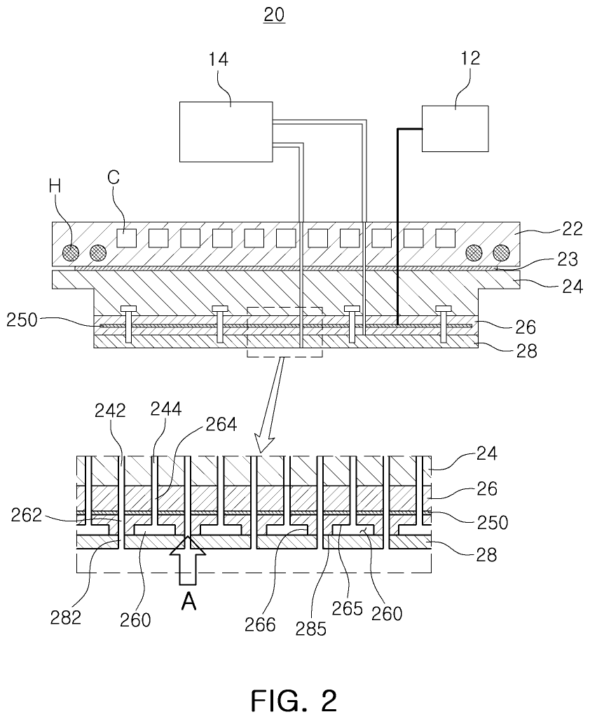

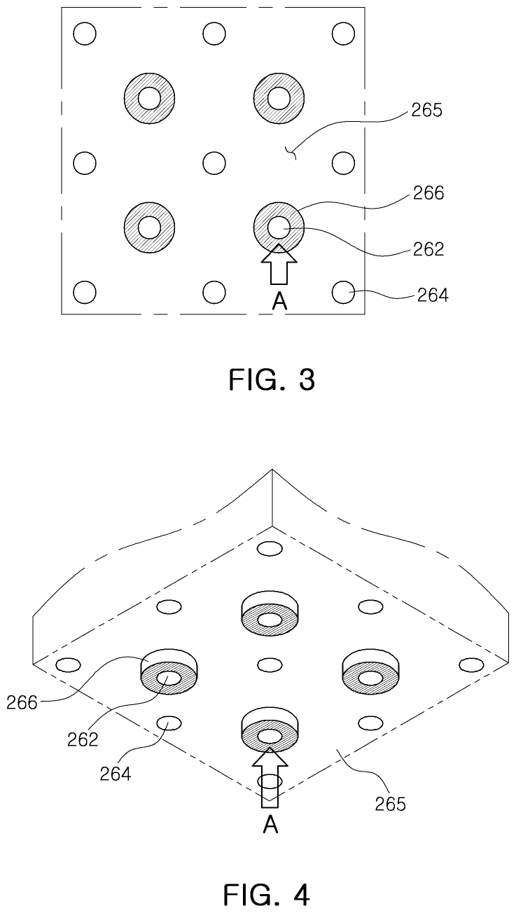

FIG. 2 is a schematic cross-sectional view of a gas supply assembly of the semiconductor wafer processing apparatus of FIG. 1, FIG. 3 is a bottom view of the showerhead viewed from a direction A of FIG. 2, and FIG. 4 is a schematic perspective view of the showerhead viewed from the direction A of FIG. 2.

Referring to FIGS. 2 to 4, the gas supply assembly 20 according to an example of the present disclosure may include a heat control plate 22, a gas distribution plate 24, a heat transfer pad 26, and the showerhead 28.

A heater H and a cooler C capable of controlling the temperature of the showerhead 28 are buried in the heat control plate 22. The cooler C may be a refrigerant pipe through which refrigerant flows. The heater H and cooler C have a limited speed of controlling the temperature of the showerhead 28 since the overall mass of the gas supply assembly 20 structure is large and due to specific heat of respective components of the gas supply assembly 20 or the thermal resistance between respective components.

When plasma P is generated in the process chamber during the process and a temperature gradient occurs in the showerhead 28, to immediately control the temperature of a specific location of the showerhead 28, the heat transfer pad 26 serves as a variable resistor.

The gas distribution plate 24 is disposed between the heat control plate 22 and the heat transfer pad 26. A heat control pad 23 may be disposed between the heat control plate 22 and the gas distribution plate 24.

The gas distribution plate 24 is disposed below the heat control plate 22, and a process gas distribution passage 242 through which process gas is delivered and a heat regulating gas distribution passage 244 through which heat regulating gas is delivered are formed in the gas distribution plate 24.

The heat transfer pad 26 is a dielectric material pad disposed below the gas distribution plate 24, and an electrode 250 is buried inside the heat transfer pad 26.

The heat transfer pad 26 is provided with a process gas movement channel 262 in communication with the process gas distribution passage 242 of the gas distribution plate 24 and a heat regulating gas movement channel 264 in communication with the heat regulating gas distribution passage 244 of the gas distribution plate 24.

The showerhead 28 is provided with a spraying nozzle 282 communicating with the process gas distribution passage 242 of the gas distribution plate 24 and discharging the process gas.

The process gas supplied from the gas supply unit 14 and passing through the process gas distribution passage 242 of the gas distribution plate 24 is sprayed onto the wafer W through the spraying nozzle 282 of the showerhead 28.

The process gas may include one or multiple source gases. A plurality of the spraying nozzles 282 may uniformly apply the process gas to the wafer W to control the distribution of the thickness of a deposition material.

In addition, the heat regulating gas is supplied from the gas supply unit 14 and moves to the heat regulating gas distribution passage 244 of the gas distribution plate 24 and the heat regulating gas movement channel 264 of the heat transfer pad 26.

The heat regulating gas moved to the heat regulating gas transfer channel 264 is moved to a gas collecting portion 260, that is provided between the showerhead 28 and the heat transfer pad 26 and is in contact with the showerhead 28, and is collected.

The heat regulating gas collected in the gas collecting portion 260 may be at least one from among He, Ar, or N₂, and may control the temperature of the upper surface of the showerhead 28. During the process, in the case in which the temperature of the showerhead 28 is high in a specific location, a relatively large amount of heat regulating gas may be provided to lower the temperature of the showerhead 28 in the specific location. If the temperature of the showerhead 28 is low in a specific location, the temperature of the showerhead 28 at the specific location may be increased by stopping or reducing the supply of heat regulating gas.

By controlling the heat regulating gas as described above, the temperature may be adjusted in a specific location of the showerhead 28.

The heat transfer pad 26 includes a lower surface that contacts an upper closed surface 285 of the showerhead 28 and further includes a cavity groove 265 that does not contact the upper closed surface 285 of the showerhead 28. For example, the cavity groove 265 may be recessed in the lower surface of the heat transfer pad 26, such as to form the gas collection portion 260 and not contact the upper closed surface 285 of the showerhead 28.

The gas collecting portion 260 is a space between a partition wall portion 266, of the heat transfer pad 26, surrounding the process gas movement channel 262 of the heat transfer pad 26 and the cavity groove 265 of the heat transfer pad 26. The partition wall portion 266 contacts the upper closed surface 285 of the showerhead 28.

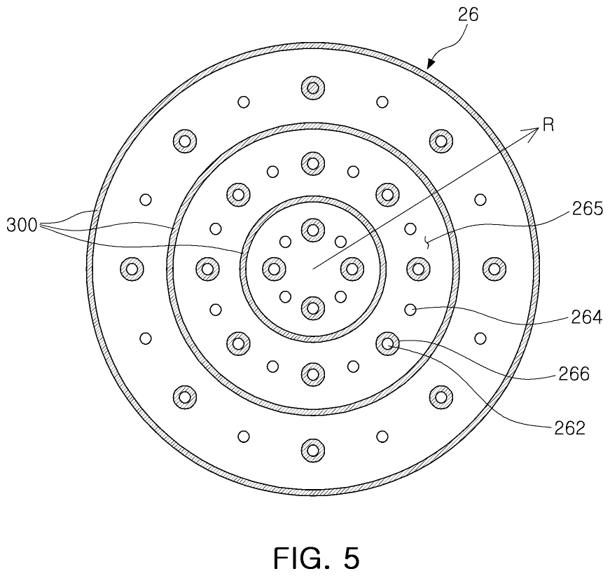

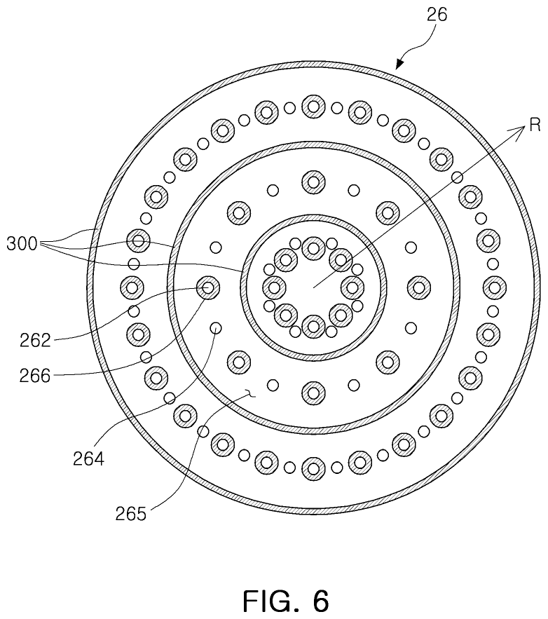

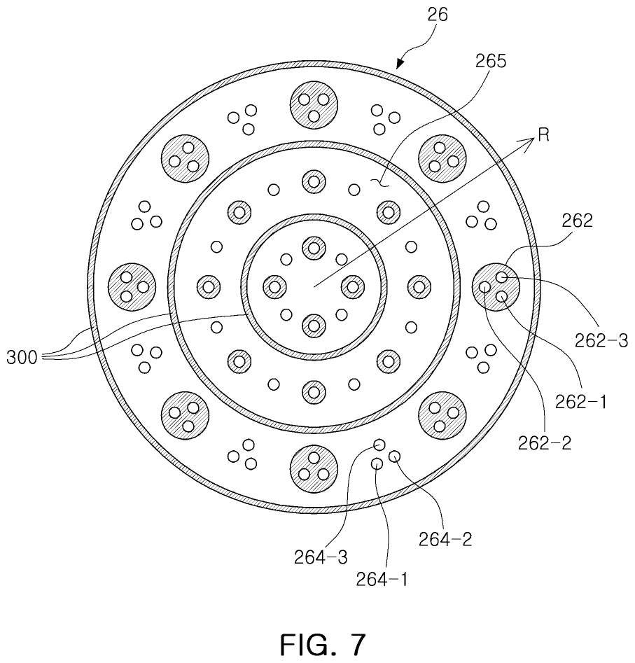

FIG. 5 is a schematic bottom view of a heat transfer pad according to an example embodiment, FIG. 6 is a schematic bottom view of a heat transfer pad according to another embodiment, and FIG. 7 is a schematic bottom view of a heat transfer pad according to another embodiment.

The cavity groove 265 formed in the lower side of the heat transfer pad 26 is divided, in a radial direction R of the heat transfer pad 26, into a plurality of cavity groove sections by a plurality of partition strips 300 in contact with the upper closed surface 285 of the showerhead 28.

In the plurality of partition strips 300 of the example embodiment of FIG. 5, the process gas movement channels 262 and the heat regulating gas movement channels 264 are disposed at equal intervals. In this case, the process gas movement channels 262 are formed in the partition wall portions 266, respectively, and the heat regulating gas movement channels 264 are formed in the cavity groove 265.

The temperature of the showerhead 28 may be controlled by controlling the pressure or amount of heat regulating gas collected in the cavity groove 265 divided by the plurality of partition strips 300. At this time, the temperature of the showerhead 28 in a specific location may be controlled by varying the pressure or amount of heat regulating gas in the cavity groove 265 divided by the plurality of partition strips 300.

In at least one of the cavity groove sections of the cavity groove 265 divided by the plurality of partition strips 300 in an example embodiment of FIG. 6, the process gas movement channels 262 and the heat regulating gas movement channels 264 are densely disposed adjacent to each other at unequal intervals. In addition, in at least another of the cavity groove sections of the cavity groove 265 divided by the plurality of partition strips 300, the process gas movement channels 262 and the heat regulating gas movement channels 264 may be densely disposed adjacent to each other at unequal intervals or are disposed at equal intervals.

In this embodiment, the temperature of the showerhead 28 may also be controlled by controlling the pressure or amount of heat regulating gas collected in the cavity groove 265 divided by the plurality of partition strips 300. At this time, the temperature of the showerhead 28 in a specific location may be controlled by varying the pressure or amount of heat regulating gas in the cavity groove 265 divided by the plurality of partition strips 300.

In an example embodiment of FIG. 7, at least one of the cavity groove sections of the cavity groove 265 divided by a plurality of partition strips 300 is provided with a plurality of process gas movement channels 262-1, 262-2, and 262-3 within the partition wall portion 266. In this case, a plurality of heat regulating gas movement channels 264-1, 264-2, and 264-3 may be disposed in the same number and/or arrangement as the number and/or arrangement of the process gas movement channels 262-1, 262-2, and 262-3. For example, as shown in FIG. 7, in an outer one of the cavity groove sections of the cavity groove 265, the process gas movement channels 262-1, 262-2, and 262-3 and the heat regulating gas movement channels 264-1, 264-2, and 264-3 are each provided in groups of three adjacent channels such that each group has a triangle shape.

In this embodiment, the temperature of the showerhead 28 may also be controlled by controlling the pressure or amount of heat regulating gas collected in the cavity groove 265 divided by the plurality of partition strips 300. At this time, the temperature of the showerhead 28 in a specific location may be controlled by varying the pressure or amount of heat regulating gas in the cavity groove 265 divided by the plurality of partition strips 300.

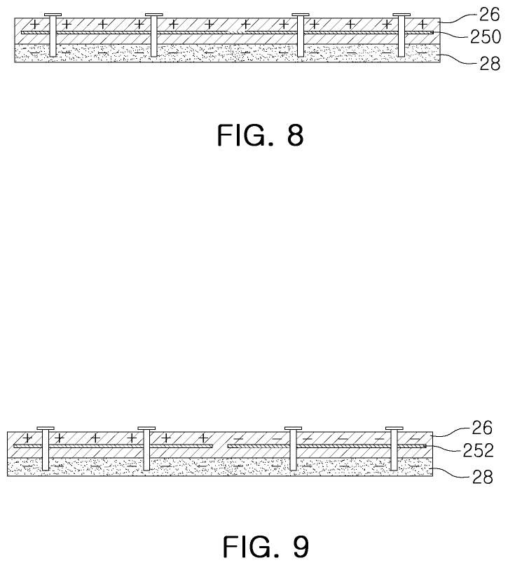

FIG. 8 is a schematic diagram illustrating an electrical connection between an electrode embedded in a heat transfer pad and a showerhead according to an example embodiment, and FIG. 9 is a schematic diagram illustrating an electrical connection between the showerhead and the electrode embedded in a heat transfer pad according to another embodiment.

The electrode 250 embedded in the heat transfer pad 26 of the example embodiment of FIG. 8 is a direct current (DC) electrode, and the DC electrode is a monopolar electrode.

A dielectric material of the heat transfer pad 26 includes at least one from among AlN and Al₂O₃, and the showerhead 28 includes a silicon material doped with a conductive material. The doped conductive material may be boron (B).

By providing a + electrode to the monopolar electrode of the heat transfer pad 26, since there is a portion of the heat transfer pad 26 formed of dielectric material between the electrode 250 (e.g., the DC electrode) and the showerhead 28, the negative(−) electrode is induced in the showerhead 28. The negative(−) electrode is derived from a plasma source within the process chamber 10.

The heat transfer pad 26 and the showerhead 28 are mechanically coupled by bolting or riveting, and may also be electrically clamping-coupled by applying a voltage to the electrode 250 of the heat transfer pad 26 so that an opposite voltage is conducted to the showerhead 28.

A plurality of electrodes 252 embedded in the heat transfer pad 26 of the example embodiment of FIG. 9 are also DC electrodes, and the DC electrodes are bipolar electrodes.

A dielectric material of the heat transfer pad 26 includes at least one from among AlN and Al₂O₃, and the showerhead 28 includes a silicon material doped with a conductive material. The doped conductive material may be Br.

By providing a + electrode to one of the electrodes 252 (e.g., bipolar electrodes) of the heat transfer pad 26 and a − electrode to the other, since there is a portion of the heat transfer pad 26 formed of dielectric material between the electrode 252 and the showerhead 28, the − electrode is charged to the showerhead 28.

Even if one from among the showerhead 28 and the electrodes 252 is charged with voltage of a same polarity, electrical clamping is possible because the potential difference is large.

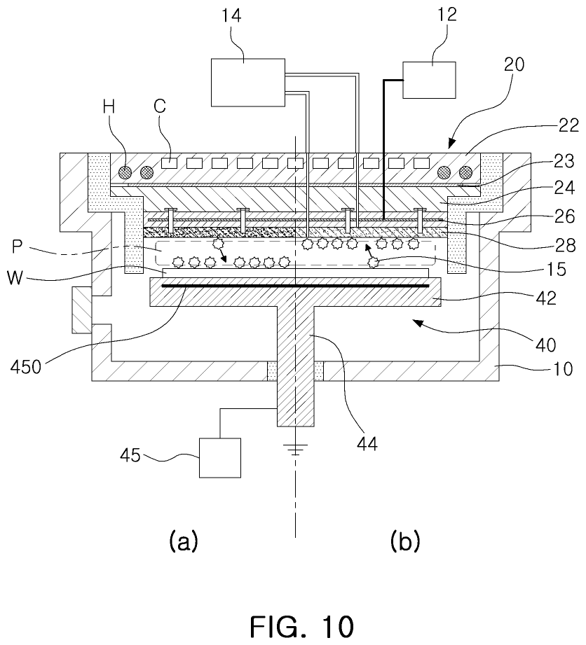

FIG. 10 is a schematic diagram illustrating the operation of a plasma polymer according to showerhead temperature control in a semiconductor wafer processing apparatus according to an example embodiment of the present disclosure.

In the semiconductor wafer processing apparatus 1 according to an example embodiment, temperature control of the showerhead 28 mechanically and electrically coupled to the heat transfer pad 26 is implemented as follows.

Portion (a) of FIG. 10 illustrates a case in which the temperature of the showerhead 28 is high, and portion (b) of FIG. 10 illustrates a case in which the temperature of the showerhead 28 is low.

As an example, when a high aspect ratio contact etching process is performed on the wafer W on the electrostatic chuck 42 in the process chamber 10 in which the plasma P has been generated, the surface temperature of the showerhead 28 of the gas supply assembly 20 is a factor that greatly affects the reliability of the etching process.

When the surface temperature of the showerhead 28 is high (see portion (a)), since a polymer 15 of the plasma P accumulates in the direction toward the wafer W, clogging (Not Open, NOP) occurs during etching. In this case, the surface temperature of the showerhead 28 should be lowered, and thus, the pressure or amount of heat transfer gas in the gas collecting portion 260 is increased. By increasing the pressure or amount of heat transfer gas in the gas collecting portion 260 (see FIG. 2), the surface temperature of the showerhead 28 decreases and the polymer 15 of the plasma P moves toward the showerhead 28.

When the surface temperature of the showerhead 28 is low (see portion (b)), the polymer 15 in the plasma is concentrated on the showerhead 28, causing a greater plasma reaction and widening the mask and thus causing a problem in which the bowing critical dimension (CD) of the wafer W increases. In this case, the surface temperature of the showerhead 28 should be increased, and thus the pressure or amount of heat transfer gas in the gas collecting portion 260 is reduced. By reducing the pressure or amount of heat transfer gas in the gas collecting portion 260, the surface temperature of the showerhead 28 increases and the polymer 15 in the plasma P moves toward the wafer W.

Using the above principle, the surface temperature of the showerhead 28 may be controlled in a specific position, thereby reducing the clogging (Not Open, NOP) phenomenon when etching the wafer W and enabling uniform etching throughout the wafer W.

As set forth above, in the gas supply assembly and the semiconductor wafer processing apparatus according to example embodiments, occurrence of clogging may be reduced even in a high aspect ratio contact process by controlling temperature of a showerhead at high speed, and a bowing critical dimension may be appropriately maintained by preventing over-etching of a mask.

Additionally, in the gas supply assembly and the semiconductor wafer processing apparatus according to example embodiments, a specific wafer area in which a processing process is performed, may be independently controlled, thereby obtaining efficient and stable process yield.

According to embodiments of the present disclosure, the semiconductor wafer processing apparatus 1 may further include a controller that is configured to control various components of the semiconductor wafer processing apparatus 1 to perform their functions. For example, the controller may be configured to control the power supply device 12, the gas supply unit 14, the heater H, the cooler C, the power supply unit 45, the heating pattern 450, the electrode 250, etc., to perform their respective functions.

While non-limiting example embodiments have been illustrated in the drawings and described above, it will be apparent to those skilled in the art that modifications and variations can be made without departing from the scope of the present disclosure as defined by the appended claims.

What is claimed is:

1. A gas supply assembly comprising:
a heat control plate comprising a heater and a cooler;
a gas distribution plate below the heat control plate and comprising at least one process gas distribution passage a process gas, and at least one heat regulating gas distribution passage configured to deliver a heat regulating gas;
a showerhead a spraying nozzle in communication with the at least one process gas distribution passage of the gas distribution plate, the spraying nozzle being configured to discharge the process gas;
a heat transfer pad below the gas distribution plate and contacting the showerhead, the heat transfer pad comprising:
a dielectric material pad;
an electrode in the dielectric material pad;
at least one process gas movement channel in communication with the at least one process gas distribution passage of the gas distribution plate; and
at least one heat regulating gas movement channel in communication with the at least one heat regulating gas distribution passage of the gas distribution plate; and
at least one gas collecting portion between the showerhead and the heat transfer pad and communicating with the at least one heat regulating gas movement channel of the heat transfer pad, each of the at least one gas collecting portion being a space configured to collect the heat regulating gas therein.

2. The gas supply assembly of claim 1, wherein the heat transfer pad further comprises:
a lower surface contacting an upper closed surface of the showerhead;
at least one partition wall portion surrounding the at least one process gas movement channel; and
a cavity groove that is not in contact with the upper closed surface of the showerhead, and
wherein each of the at least one gas collecting portion is a space between the cavity groove of the heat transfer pad and one of the at least one partition wall portion of the heat transfer pad.

3. The gas supply assembly of claim 2, wherein the cavity groove is divided, in a radial direction of the heat transfer pad, into a plurality of cavity groove sections by a plurality of partition strips that contact the upper closed surface of the showerhead.

4. The gas supply assembly of claim 3, wherein the at least one process gas movement channel is a plurality of process gas movement channels,
wherein the at least one heat regulating gas movement channel is a plurality of heat regulating gas movement channels, and
wherein the plurality of process gas movement channels and the plurality of heat regulating gas movement channels are disposed at equal intervals within the plurality of partition strips.

5. The gas supply assembly of claim 3, wherein the at least one process gas movement channel is a plurality of process gas movement channels,
wherein the at least one heat regulating gas movement channel is a plurality of heat regulating gas movement channels, and
wherein, in at least one from among the plurality of cavity groove sections, the plurality of process gas movement channels and the plurality of heat regulating gas movement channels are disposed adjacent to each other at unequal intervals, and are more densely disposed in the at least one from among the plurality of cavity groove sections than in another one from among the plurality of cavity groove sections.

6. The gas supply assembly of claim 3, wherein the at least one process gas movement channel is a plurality of process gas movement channels, and
wherein, in at least one from among the plurality of cavity groove sections, two or more of the plurality of process gas movement channels is in a single partition wall portion from among the at least one partition wall portion.

7. The gas supply assembly of claim 6, wherein the at least one heat regulating gas movement channel is a plurality of heat regulating gas movement channels, and
wherein a total number of the plurality of heat regulating gas movement channels is equal to a total number of the plurality of process gas movement channels.

8. The gas supply assembly of claim 1, wherein the dielectric material pad comprises at least one from among AlN and Al₂O₃, and
wherein the showerhead comprises a silicon material doped with a conductive material.

9. The gas supply assembly of claim 1, wherein the electrode of the heat transfer pad is a direct current (DC) electrode, and the DC electrode is a monopolar electrode or a bipolar electrode.

10. The gas supply assembly of claim 9, wherein the showerhead and the heat transfer pad are mechanically coupled to each other by bolting or riveting, and are electrically clamping-coupled to each other by applying a first voltage to the DC electrode of the heat transfer pad such that a second voltage is conducted to the showerhead, and
wherein the first voltage and the second voltage have opposite polarities from each other, or the first voltage and the second voltage have a same polarity but different magnitudes from each other.

11. A semiconductor wafer processing apparatus comprising:
a process chamber configured to accommodate a semiconductor wafer;
a gas supply assembly in an upper portion of the process chamber and configured to discharge a process gas to the semiconductor wafer; and
an electrostatic chuck configured to support the semiconductor wafer within the process chamber and generate plasma by opposing the gas supply assembly,
wherein the gas supply assembly comprises:
a heat control plate comprising a heater and a cooler;
a gas distribution plate below the heat control plate and comprising at least one process gas distribution passage, configured to transmit the process gas, and at least one heat transfer gas distribution passage, configured to transmit heat regulating gas;
a showerhead comprising a spraying nozzle in communication with the at least one process gas distribution passage of the gas distribution plate, the spraying nozzle configured to discharge the process gas,
a heat transfer pad below the gas distribution plate and contacting the showerhead, the heat transfer pad comprising:
a dielectric material pad;
an electrode in the dielectric material pad;
at least one process gas movement channel in communication with the at least one process gas distribution passage of the gas distribution plate; and
at least one heat regulating gas movement channel in communication with the heat regulating gas of the gas distribution plate; and
at least one gas collecting portion between the showerhead and the heat transfer pad, and in communication with the at least one heat regulating gas movement channel of the heat transfer pad, each of the at least one gas collecting portion being a space that is configured to collect the heat regulating gas therein.

12. The semiconductor wafer processing apparatus of claim 11, wherein the heat transfer pad further comprises:
a lower surface contacting an upper closed surface of the showerhead;
at least one partition wall portion surrounding the at least one process gas movement channel; and
a cavity groove that is not in contact with the upper closed surface of the showerhead, and
wherein each of the at least one gas collecting portion is a space between the cavity groove of the heat transfer pad and one of the at least one partition wall portion of the heat transfer pad.

13. The semiconductor wafer processing apparatus of claim 12, wherein the cavity groove is partitioned, in a radial direction of the heat transfer pad, into a plurality of cavity groove sections by a plurality of partition strips that contact the upper closed surface of the showerhead.

14. The semiconductor wafer processing apparatus of claim 13, wherein the at least one process gas movement channel is a plurality of process gas movement channels,
wherein the at least one heat regulating gas movement channel is a plurality of heat regulating gas movement channels, and
wherein the plurality of process gas movement channels and the plurality of heat regulating gas movement channels are disposed at equal intervals within the plurality of partition strips.

15. The semiconductor wafer processing apparatus of claim 14, wherein, in at least one from among the plurality of cavity groove sections, the plurality of process gas movement channels and the plurality of heat regulating gas movement channels are disposed adjacent to each other at unequal intervals, and are more densely disposed in the at least one from among the plurality of cavity groove sections than in another one from among the plurality of cavity groove sections.

16. The semiconductor wafer processing apparatus of claim 14, wherein, in at least one from among the plurality of cavity groove sections, two or more of the plurality of process gas movement channels is in a single partition wall portion from among the at least one partition wall portion.

17. The semiconductor wafer processing apparatus of claim 16, wherein a total number of the plurality of heat regulating gas movement channels is equal to a total number of the plurality of process gas movement channels.

18. The semiconductor wafer processing apparatus of claim 11, wherein the dielectric material pad comprises at least one from among AlN and Al₂O₃, and
wherein the showerhead comprises a silicon material doped with a conductive material.

19. The semiconductor wafer processing apparatus of claim 11, wherein the electrode of the heat transfer pad is a direct current (DC) electrode, and the DC electrode is a monopolar electrode or a bipolar electrode.

20. The semiconductor wafer processing apparatus of claim 19, wherein the showerhead and the heat transfer pad are mechanically coupled to each other by bolting or riveting, and are electrically clamping-coupled to each other by applying a first voltage to the DC electrode of the heat transfer pad such that a second voltage is conducted to the showerhead, and
wherein the first voltage and the second voltage have opposite polarities from each other, or the first voltage and the second voltage have a same polarity but different magnitudes from each other.
